(19) United States
(12) Patent Application Publication
(10) Pub. No.: US 2007/0155179 A1
(43) Pub. Date: Jul. 5, 2007

(54) METHOD TO DEFINE A PATTERN HAVING SHRUNK CRITICAL DIMENSION

(76) Inventors: Jar-Ming Ho, Taipei City (TW); Shian-Jyh Lin, Taipei County (TW); Yu-Pi Lee, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/456,207

(22) Filed: Jul. 9, 2006

(30) Foreign Application Priority Data
Dec. 30, 2005 (TW) 094147605

(51) Int. Cl. H01L 21/311; H01L 21/76; H01L 21/3205; H01L 21/302

(52) U.S. Cl. 438/700; 438/424; 438/719; 438/589

(57) ABSTRACT

The present invention provides a method for fabricating a trench opening in a semiconductor substrate. The patterned amorphous silicon layer is completely oxidized to form a silicon oxide mask having openings with shrunk critical dimensions. The silicon oxide mask is used as an etching hard mask in the subsequent trench etching process. The present invention is not only suited for the fabrication of trench-capacitor DRAM devices, but also suited for the semiconductor contact/via processes.

### BACKGROUND OF THE INVENTION

1. Field of the Invention

The present invention relates generally to a method for fabricating semiconductor devices. More specifically, the present invention relates to a two-stage method to define a pattern having shrunk critical dimension by oxidizing an amorphous silicon hard mask.

2. Description of the Prior Art

Integrated circuit devices are continually being made smaller in order to increase speed, make the device more portable and to reduce the cost of manufacturing the device. However, certain designs have a minimum feature size, which cannot be reduced without compromising the integrity of electrical isolation between devices and consistent operation of the device.

Integrated circuits, such as ultra-large scale integrated (ULSI) circuits, can include as many as one billion transistors or more. Most typically, ULSI circuits are formed of Field Effect Transistors (FETs) formed in a Complementary Metal Oxide Semiconductor (CMOS) process. Each MOSFET includes a gate electrode formed over a channel region of the semiconductor substrate, which runs between a drain region and source region. To increase the device density and operation speed of the integrated circuits, the feature size of transistor within the circuits must be reduced. However, with the continued reduction in device size, sub-micron scale MOS transistors have to overcome many technical challenges. As the MOS transistors become narrower, that is, their channel length decreases, problems such as junction leakage, source/drain breakdown voltage, and data retention time become more pronounced.

One solution to decrease the physical dimension of ULSI circuits is to form recessed gate or “trench-type” transistors, which have a gate electrode buried in a groove formed in a semiconductor substrate. This type of transistor reduces short channel effects by effectively lengthening the effective channel length by having the gate extend into the semiconductor substrate.

However, the conventional method of fabricating recessed-gate MOS transistor has several drawbacks. The gate trenches are etched into the wafer by using a dry etching process. The variation of the depth of the gate trenches across the wafer causes the inconsistence of the channel length for each transistor, and thus adversely affects the threshold voltage control.

Further, when the critical dimension of the gate trench shrinks to sub-0.1 micron scale, the size of the gate trench is normally less than 1 F. Such small size gate trench also challenges the conventional lithographic process. A so-called “line edge roughness (LER)” effect and trench profile control problems arise.

### SUMMARY OF THE INVENTION

It is one object of the present invention to provide a method to define a pattern having shrunk critical dimension in order to solve the above-mentioned problems.

According to the claimed invention, a method to define a pattern having shrunk critical dimension by oxidizing an amorphous silicon hard mask is disclosed. The method includes the following steps:

(a) forming an amorphous silicon layer on a semiconductor substrate;

(b) patterning said amorphous silicon layer to form a first opening in said amorphous silicon layer having a first critical dimension;

(c) performing an oxidization process to transforming said amorphous silicon layer into a silicon oxide mask, and shrinking said first opening to a second opening having a second critical dimension; and

(d) using said silicon oxide mask as an etching hard mask, etching said semiconductor substrate through the second opening, thereby forming a trench in said semiconductor substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-4 are schematic, cross-sectional diagrams illustrating a method to define a pattern having shrunk critical dimension by oxidizing an amorphous silicon hard mask in accordance with one preferred embodiment of this invention.

### DETAILED DESCRIPTION

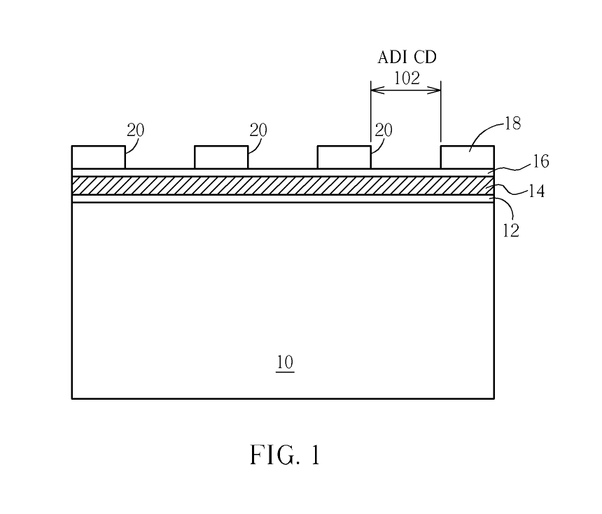

Please refer to FIGS. 1-4. FIGS. 1-4 are schematic, cross-sectional diagrams illustrating a method to define a pattern having shrunk critical dimension by oxidizing an amorphous silicon hard mask in accordance with one preferred embodiment of this invention. As shown in FIG. 1, a semiconductor substrate 10 such as a silicon substrate is provided. A silicon nitride liner 12 is deposited on the surface of the semiconductor substrate 10.

An amorphous silicon layer 14 is then deposited over the silicon nitride liner 12. A bottom anti-reflection coating (BARC) layer 16 is formed on the amorphous silicon layer 14. The BARC layer 16 may be silicon oxy-nitride layer, but not limited thereto.

According to the preferred embodiment, the silicon nitride liner 12 has a thickness of about 30-100 angstroms. The amorphous silicon layer 14 has a thickness of about 10-50 angstroms, but not limited thereto.

Subsequently, a lithographic process is carried out to form a patterned photoresist layer 18 on the BARC layer 16. The patterned photoresist layer 18 has a plurality of openings 20 that expose a portion of the underlying BARC layer 16. The opening 20 has an after-development-inspection critical dimension (ADI CD) 102.

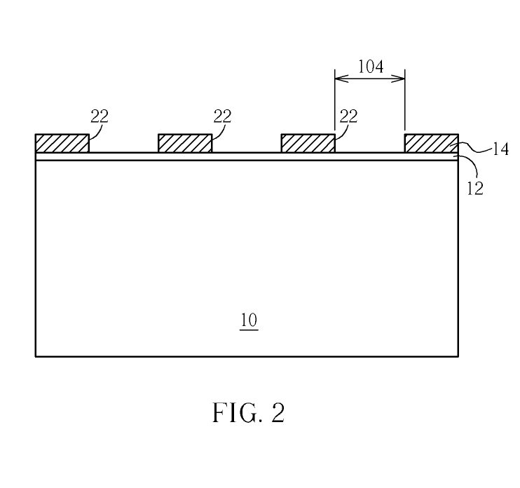

As shown in FIG. 2, using the patterned photoresist layer 18 as an etching hard mask, a dry etching process is performed to etch the exposed BARC layer 16 and the amorphous silicon layer 14 through the openings 20, thereby transferring opening 20 pattern to the amorphous silicon layer 14 and forming openings 22. Thereafter, the photoresist layer 18 and the BARC layer 16 are stripped. The openings 22 etched into the amorphous silicon layer 14 have an after-etch-inspection critical dimension (AEI CD) 104. According to the preferred embodiment, the AEI CD 104 is approximately equal to the ADI CD 102.

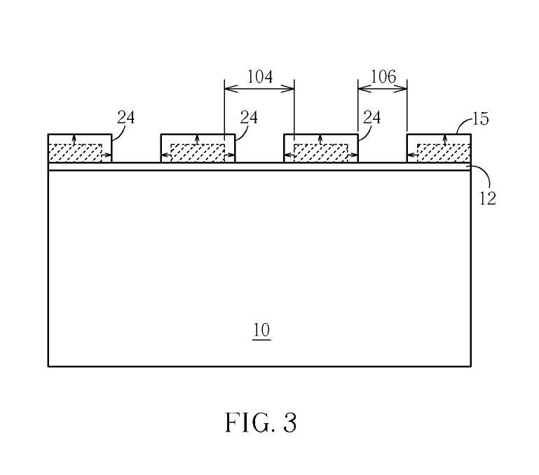

As shown in FIG. 3, an oxidization process is carried out to transform the patterned amorphous silicon layer 14 into silicon oxide, thereby forming a silicon oxide mask 15.

In FIG. 3, the dark regions indicated with dash lines represent the patterned amorphous silicon layer 14 prior to oxidization. The oxidization process shrinks the openings 22 due to expansion in volume during the transformation from amorphous silicon into silicon oxide. After oxidization, the openings 22 become openings 24 that have a shrunk critical dimension 106 that is smaller than AEI CD 104.

During the oxidization, since the semiconductor substrate 10 is covered with the silicon nitride liner 12, the surface of the semiconductor substrate 10 is not oxidized.

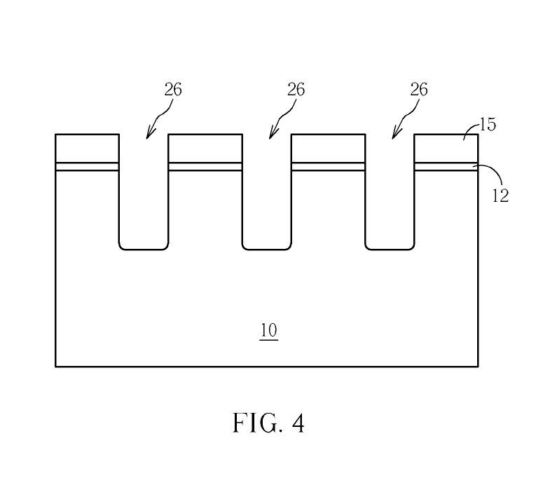

As shown in FIG. 4, after completely oxidizing the patterned amorphous silicon layer 14 into the silicon oxide mask 15, another dry etching process is carried out. The silicon oxide mask 15 is used an etching hard mask in this dry etching process. The exposed silicon nitride liner 12 and the semiconductor substrate 10 is etched through the openings 24, thereby forming trenches 26.

It is one salient feature of the present invention that the formation of the trench 26 is carried out in two-stage. The trench pattern of the photoresist layer 18 is first transferred to the amorphous silicon layer 14, and then the photoresist layer 18 is removed. The amorphous silicon layer 14 is then oxidized to shrink the critical dimension of the transferred trench pattern. Thereafter, the trench pattern having shrunk CD is then transferred into the semiconductor substrate. By doing this, the thickness of the photoresist layer 18 can be thinner than the prior art method and the so-called “line edge roughness (LER)” effect can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method to define a pattern having shrunk critical dimension by oxidizing an amorphous silicon hard mask, comprising:
forming an amorphous silicon layer on a semiconductor substrate;
patterning said amorphous silicon layer to form a first opening in said amorphous silicon layer having a first critical dimension;
performing an oxidization process to transforming said amorphous silicon layer into a silicon oxide mask, and shrinking said first opening to a second opening having a second critical dimension; and
using said silicon oxide mask as an etching hard mask, etching said semiconductor substrate through the second opening, thereby forming a trench in said semiconductor substrate.

2. The method according to claim 1 further comprising a step of forming a liner on said semiconductor substrate prior to forming said amorphous silicon layer on said semiconductor substrate.

3. The method according to claim 2 wherein said liner comprises silicon nitride.

4. The method according to claim 2 wherein said liner has a thickness of 30-100 angstroms.

5. The method according to claim 1 wherein said amorphous silicon layer has a thickness of 10-50 angstroms.

6. The method according to claim 1 wherein said second critical dimension is smaller than the first critical dimension.
